(19) United States
(12) Patent Application Publication
(10) Pub. No.: US 2019/0378740 A1
(43) Pub. Date: Dec. 12, 2019

(54) TEACHING APPARATUS AND TEACHING METHOD FOR SUBSTRATE TRANSFER SYSTEM

(71) Applicant: EBARA CORPORATION, Tokyo (JP)

(72) Inventors: Hidetatsu Isokawa, Tokyo (JP); Koichi Hashimoto, Tokyo (JP); Mitsuhiko Inaba, Tokyo (JP); Makoto Iida, Tokyo (JP)

(21) Appl. No.: 16/438,295

(22) Filed: Jun. 11, 2019

(30) Foreign Application Priority Data
Jun. 12, 2018 (JP) 111666/2018

(51) Int. Cl. H01L 21/68; H01L 21/677; B25J 9/16; B65G 47/90

(52) U.S. Cl. CPC H01L 21/681; B65G 47/905; B25J 9/163; H01L 21/67739

(57) ABSTRACT

There is provided a teaching apparatus for a substrate transfer system including a substrate transfer device and a substrate receiving device. The substrate transfer device is configured to hold a substrate. The substrate receiving device is configured to receive the substrate from the substrate transfer device. The teaching apparatus includes a teaching substrate configured to be held to the substrate transfer device, a camera mountable to the teaching substrate, and a controller that controls an operation of the substrate transfer device holding the teaching substrate and/or the substrate receiving device.

### CROSS-REFERENCE TO RELATED APPLICATION

This application is based upon and claims the benefit of priority of the prior Japanese Patent Application No. 2018-111666, filed on Jun. 12, 2018, the entire content of which is incorporated herein by reference.

### TECHNICAL FIELD

This application relates to a teaching apparatus and a teaching method for a substrate transfer system.

### BACKGROUND ART

In recent years, with the progress of the higher integration of semiconductor devices, circuit wiring is becoming finer, and an inter-wiring distance is becoming narrower. In manufacturing of the semiconductor device, many kinds of materials are repeatedly formed in a film shape on a silicon substrate to form a layered structure. In order to form this layered structure, a technique to planarize a surface of the substrate is critical. As such means of planarizing the surface of the substrate, a polishing device for performing a chemical-mechanical polishing (CMP) (also referred to as a chemical-mechanical polishing device) has been used widely.

The chemical-mechanical polishing (CMP) device is generally provided with a polishing table attached with a polishing pad, a top ring for holding a substrate, and a nozzle for supplying polishing liquid on the polishing pad. While the nozzle supplies the polishing liquid on the polishing pad, the top ring presses the substrate against the polishing pad, and the top ring and the polishing table are relatively moved, thereby to polish the substrate to planarize the surface of the substrate.

There may be a case where a substrate processing apparatus includes a CMP unit to perform CMP, a cleaning unit for cleaning the substrate after polishing, and further a drying unit for drying the substrate after cleaning. The substrate processing apparatus includes a substrate transfer system to move the substrate between the respective units.

### CITATION LIST

### Patent Literature

PTL 1: Japanese Unexamined Patent Application Publication No. 2017-183647

### SUMMARY OF INVENTION

### Technical Problem

The substrate processing apparatus has been desired to shorten a start-up time and a maintenance period. The substrate processing apparatus includes the substrate transfer system that holds the substrate with a robot arm and the like or places the substrate on a movable stage to move. To accurately transfer the substrate, a work (teaching work) teaching stop positions of the robot arm holding the substrate and the movable stage need to be performed. Conventionally, a person performs such teaching work while visually checking the stop position of the substrate, and this has required a lot of time to perform the teaching work at the start-up and during the maintenance. Moreover, a problem arises that accuracy of the work varies depending on experience and a skill of a worker who performs the teaching work. One object of this application is to provide a technique that allows performing teaching irrespective of a skill of a worker who performs a teaching work.

### Solution to Problem

There is provided a teaching apparatus for a substrate transfer system including a substrate transfer device and a substrate receiving device. The substrate transfer device is configured to hold a substrate. The substrate receiving device is configured to receive the substrate from the substrate transfer device. The teaching apparatus includes a teaching substrate configured to be held to the substrate transfer device, a camera mountable to the teaching substrate, and a controller that controls an operation of the substrate transfer device holding the teaching substrate and/or the substrate receiving device. The controller includes a receiving unit that receives an image photographed by the camera, an analyzer that calculates a relative positional relationship between the substrate transfer device and the substrate receiving device from the received image, and a determining unit that determines a stop position of the substrate transfer device and/or the substrate receiving device based on the relative positional relationship between the substrate transfer device and the substrate receiving device calculated by the analyzer.

### BRIEF DESCRIPTION OF DRAWINGS

FIG. 1 is a plan view illustrating an overall configuration of a substrate processing apparatus according to one embodiment;

FIG. 2 is an exploded perspective view illustrating an internal configuration of a transfer unit according to the one embodiment;

FIG. 3 is a perspective view schematically illustrating a first polishing device according to the one embodiment;

FIG. 4 is a side view illustrating a transfer robot according to the one embodiment;

FIG. 5 is a perspective view illustrating a first transfer unit according to the one embodiment;

FIG. 6 is a drawing schematically illustrating a configuration of a teaching apparatus according to the one embodiment;

FIG. 7 is a perspective view illustrating a teaching substrate according to one embodiment;

FIG. 8 is a flowchart depicting a teaching method for a substrate transfer system according to one embodiment;

FIG. 9 is a side view schematically illustrating a state where a first stage in an exchanger according to the one embodiment moves near just above a first pusher; and

FIG. 10 is a drawing schematically illustrating an image photographed when the first stage and the first pusher in the exchanger according to the one embodiment are in the state illustrated in FIG. 9.

### DESCRIPTION OF EMBODIMENTS

The following describes embodiments of a teaching apparatus and a substrate processing apparatus using the teaching apparatus according to the present invention with the attached drawings. In the attached drawings, identical or similar reference numerals are attached to identical or similar components, and overlapping description regarding the identical or similar components may be omitted in the description of the respective embodiments. Features shown in the respective embodiments are applicable to other embodiments in so far as they are consistent with one another.

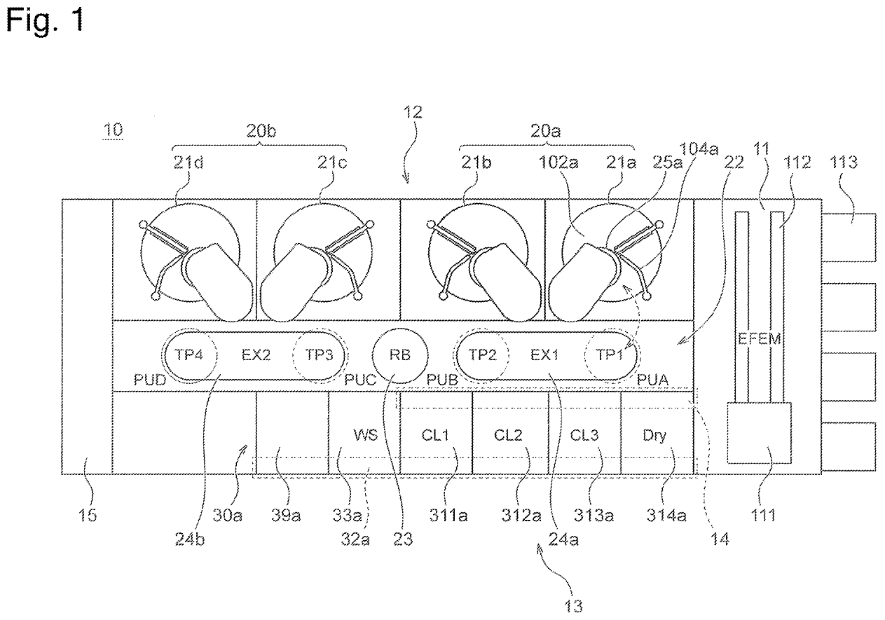

FIG. 1 is a plan view illustrating an overall configuration of the substrate processing apparatus according to one embodiment. As illustrated in FIG. 1, a substrate processing apparatus 10 according to the embodiment includes a housing having an approximately rectangular shape in plan view inside of which is partitioned by partition walls to provide a loading/unloading unit 11, a polishing unit 12, a cleaning unit 13, and a transfer unit 14. These loading/unloading unit 11, polishing unit 12, cleaning unit 13, and transfer unit 14 are each independently assembled and are independently exhausted. The substrate processing apparatus 10 further includes a control unit 15 (also referred to as a control panel) that controls operations of the loading/unloading unit 11, the polishing unit 12, the cleaning unit 13, and the transfer unit 14.

<Loading/Unloading Unit>

The loading/unloading unit 11 includes a plurality of (four in the illustrated example) front loading units 113 on which substrate cassettes to stock many substrates W are placed. These front loading units 113 are arrayed adjacent to a width direction (a direction perpendicular to a longitudinal direction) of the substrate processing apparatus 10. On the front loading unit 113, an open cassette, a Standard Manufacturing Interface (SMIF) pod, or a Front Opening Unified Pod (FOUP) is mountable. SMIF and FOUP are sealing containers that internally house the substrate cassettes and cover the substrate cassettes with partition walls to ensure maintaining an environment independent from an external space.

A running mechanism 112 is laid along the array direction of the front loading units 113 in the loading/unloading unit 11. A transfer robot 111 movable along the array direction of the front loading units 113 is installed on this running mechanism 112. The transfer robot 111 moving on the running mechanism 112 can access the substrate cassettes mounted to the front loading units 113. This transfer robot 111 includes two hands on the top and bottom. For example, the substrate W is returned to the substrate cassette by the upper hand and the substrate W before polishing is transferred by the lower hand, and thus the upper and lower hands are usable according to the purpose. Instead of this configuration, the substrate W may be transferred by only a single hand.

Since the loading/unloading unit 11 is a region need to be maintained clean most, an inside of the loading/unloading unit 11 is always maintained at a pressure higher than all of outside the apparatus, the polishing unit 12, the cleaning unit 13, and the transfer unit 14. On the upper side of the running mechanism 112 of the transfer robot 111, a filter fan unit (not illustrated) including a clean air filter such as a HEPA filter and a ULPA filter is disposed. This filter fan unit always blows out clean air after particles, toxic vapor, and gas are removed downward.

<Transferring Unit>

The transfer unit 14 is a region that transfers the substrate before polishing from the loading/unloading unit 11 to the polishing unit 12 and extends along the longitudinal direction of the substrate processing apparatus 10. As illustrated in FIG. 1, the transfer unit 14 is located adjacent to both of the loading/unloading unit 11, the cleanest region, and the polishing unit 12, the dirtiest region. Therefore, to avoid the particles inside the polishing unit 12 to pass through the transfer unit 14 and diffuse into the loading/unloading unit 11, as described later, an airflow flowing from the loading/unloading unit 11 side to the polishing unit 12 side is generated inside the transfer unit 14.

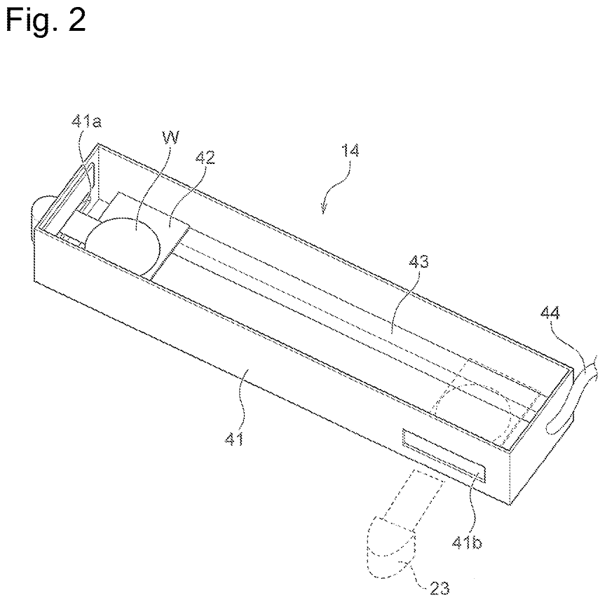

FIG. 2 is an exploded perspective view illustrating an internal configuration of the transfer unit 14. As illustrated in FIG. 2, the transfer unit 14 includes a cover 41 extending in the longitudinal direction, a sliding stage 42, a stage moving mechanism 43, and an exhaust duct 44. The sliding stage 42 is located inside the cover 41 and holds the substrate W. The stage moving mechanism 43 is configured to linearly move the sliding stage 42 along the longitudinal direction. The exhaust duct 44 exhausts air inside the cover 41.

The cover 41 has a bottom plate, four side plates, and a top plate (not illustrated in FIG. 2). Among these plates, a carry-in port 41a communicating with the loading/unloading unit 11 is formed on one of the side plates in the longitudinal direction. A carry-out port 41b communicating with the polishing unit 12 is formed on an end on a side opposite to the carry-in port 41a on one of the side plates in a width direction. The carry-in port 41a and the carry-out port 41b are openable/closable with shutters (not illustrated). The transfer robot 111 in the loading/unloading unit 11 can access the sliding stage 42 inside the cover 41 from the carry-in port 41a. A transfer robot 23 in the polishing unit 12 can access the sliding stage 42 inside the cover 41 from the carry-out port 41b.

As the stage moving mechanism 43, for example, a motor-driving mechanism using a ball screw or an air cylinder is used. The sliding stage 42 is fixed to a movable part of the stage moving mechanism 43 and is linearly moved inside the cover 41 along the longitudinal direction by a power given from the stage moving mechanism 43.

The sliding stage 42 includes four pins protruding upward on its outer peripheral portion. The substrate W, which is placed on the sliding stage 42 by the transfer robot 111 in the loading/unloading unit 11, is supported on the sliding stage 42 with its outer peripheral edge guided and positioned with the four pins. These pins are made of resin such as polypropylene (PP), polychlorotrifluoroethylene (PCTFE), and polyether ether ketone (PEEK).

The exhaust duct 44 is disposed on the other side plate (the side plate on a side opposite to the carry-in port 41a) in the longitudinal direction of the cover 41. Exhausting air with the exhaust duct 44 while the carry-in port 41a is open generates an airflow flowing from the carry-in port 41a side to the carry-out port 41b side inside the cover 41. This prevents the particles inside the polishing unit 12 from passing through the transfer unit 14 and diffusing into the loading/unloading unit 11.

<Polishing Unit>

As illustrated in FIG. 1, the polishing unit 12 is a region where the substrate W is polished and includes a first polishing unit 20a, a second polishing unit 20b, and a polishing unit transfer mechanism 22. The first polishing unit 20a includes a first polishing device 21a and a second polishing device 21b. The second polishing unit 20b includes a third polishing device 21c and a fourth polishing device 21d. The polishing unit transfer mechanism 22 is located adjacent to the respective transfer unit 14, first polishing unit 20a, and second polishing unit 20b. The polishing unit transfer mechanism 22 is located between the cleaning unit 13 and the first polishing unit 20a and the second polishing unit 20b in the width direction of the substrate processing apparatus 10.

The first polishing device 21a, the second polishing device 21b, the third polishing device 21c, and the fourth polishing device 21d are arrayed along the longitudinal direction of the substrate processing apparatus 10. The second polishing device 21b, the third polishing device 21c, and the fourth polishing device 21d have configurations similar to the first polishing device 21a; therefore, the following describes the first polishing device 21a.

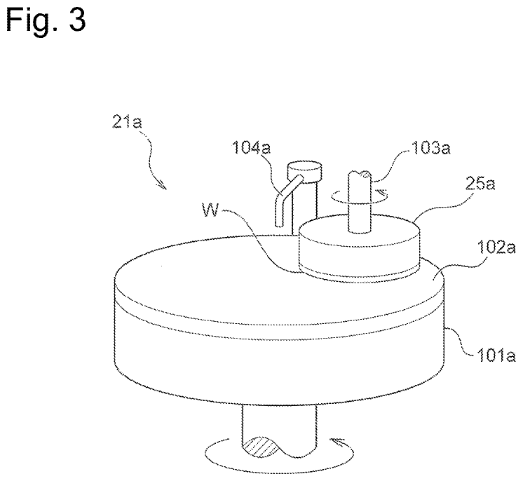

FIG. 3 is a perspective view schematically illustrating the first polishing device 21a. The first polishing device 21a includes a polishing table 101a, a top ring 25a, a polishing liquid supply nozzle 104a, a dresser (not illustrated), and an atomizer (not illustrated). A polishing pad 102a having a polishing surface is mounted to the polishing table 101a. The top ring 25a is to hold the substrate W and polish the substrate W while pressing the substrate W against the polishing pad 102a on the polishing table 101a. The polishing liquid supply nozzle 104a is to supply the polishing pad 102a with polishing liquid (also referred to as slurry) and dressing liquid (for example, pure water). The dresser dresses the polishing surface of the polishing pad 102a. The atomizer atomizes mixed gas of liquid (for example, pure water) and gas (for example, nitrogen gas) or liquid (for example, pure water) and injects the atomized liquid onto the polishing surface.

Among these members, the top ring 25a is supported to a top ring shaft 103a. The polishing pad 102a is stuck to the top surface of the polishing table 101a and has a top surface constituting a polishing surface polishing the substrate W. Instead of the polishing pad 102a, a fixed whetstone is usable. As indicated by the arrow in FIG. 3, the top ring 25a and the polishing table 101a are rotatable around their axial centers. The substrate W is held to a lower surface of the top ring 25a by vacuum suction. The polishing liquid supply nozzle 104a supplies the polishing surface of the polishing pad 102a with the polishing liquid during polishing, the substrate W, the polishing target, is pressed to the polishing surface with the top ring 25a to be polished.

As is apparent from the use of slurry during polishing, the polishing unit 12 is the dirtiest region. Accordingly, in this embodiment, air is exhausted from peripheral areas of the respective polishing tables of the first polishing device 21a, the second polishing device 21b, the third polishing device 21c, and the fourth polishing device 21d to avoid the particles in the polishing unit 12 from scattering outside. By setting a pressure inside the polishing unit 12 lower than pressures outside the apparatus, the cleaning unit 13, the loading/unloading unit 11, and the transfer unit 14 nearby, the scatter of particles is prevented. Usually, an exhaust duct (not illustrated) and a filter (not illustrated) are disposed below and above the polishing table, respectively. Air purified via these exhaust duct and filter are spouted, thus generating a downflow.

As illustrated in FIG. 1, the top ring 25a in the first polishing device 21a moves between a polishing position and a first substrate transfer position TP1 by a swing operation of a top ring head, and the substrate is delivered to the first polishing device 21a at the first substrate transfer position TP1. Similarly, a top ring 25b in the second polishing device 21b moves between a polishing position and a second substrate transfer position TP2 by a swing operation of a top ring head, and the substrate is delivered to the second polishing device 21b at the second substrate transfer position TP2. A top ring 25c in the third polishing device 21c moves between a polishing position and a third substrate transfer position TP3 by a swing operation of a top ring head, and the substrate is delivered to the third polishing device 21c at the third substrate transfer position TP3. A top ring 25d in the fourth polishing device 21d moves between a polishing position and a fourth substrate transfer position TP4 by a swing operation of a top ring head, and the substrate is delivered to the fourth polishing device 21d at the fourth substrate transfer position TP4.

The polishing unit transfer mechanism 22 includes a first transfer unit 24a that transfers the substrate W to the first polishing unit 20a, a second transfer unit 24b that transfers the substrate W to the second polishing unit 20b, and the transfer robot 23. The transfer robot 23 is located between the first transfer unit 24a and the second transfer unit 24b and delivers the substrate between the transfer unit 14, the first transfer unit 24a, and the second transfer unit 24b. In the example illustrated in the drawing, the transfer robot 23 is located at the approximately center on the housing of the substrate processing apparatus 10.

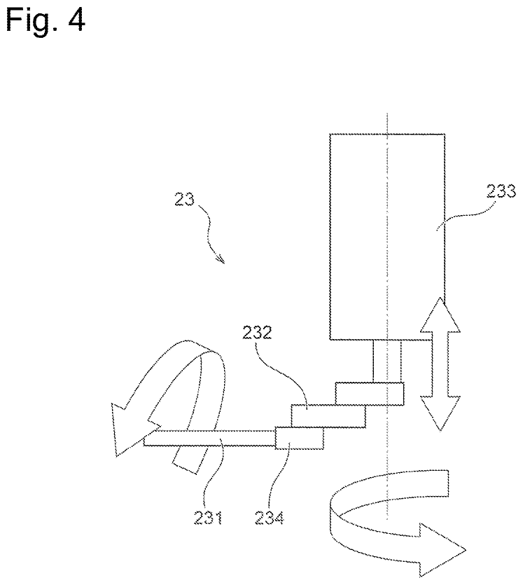

FIG. 4 is a side view illustrating the transfer robot 23. As illustrated in FIG. 4, the transfer robot 23 includes a hand 231 holding the substrate W, a reversing mechanism 234 that reverses the top and bottom of the hand 231, an extendable arm 232 that supports the hand 231, and a robot body 233. The robot body 233 includes an arm up-down movement mechanism that moves the arm 232 up and down and an arm turning mechanism that turns the arm 232 around the vertical axis line. The robot body 233 is suspended to a frame of a ceiling of the substrate processing apparatus 10 to be mounted.

In this embodiment, the hand 231 can access the sliding stage 42 from the carry-out port 41b in the transfer unit 14. The hand 231 can also access the first transfer unit 24a and the second transfer unit 24b in the polishing unit 12. Accordingly, the transfer robot 23 distributes the substrates W continuously transferred from the transfer unit 14 to the polishing unit 12 to the first transfer unit 24a and the second transfer unit 24b.

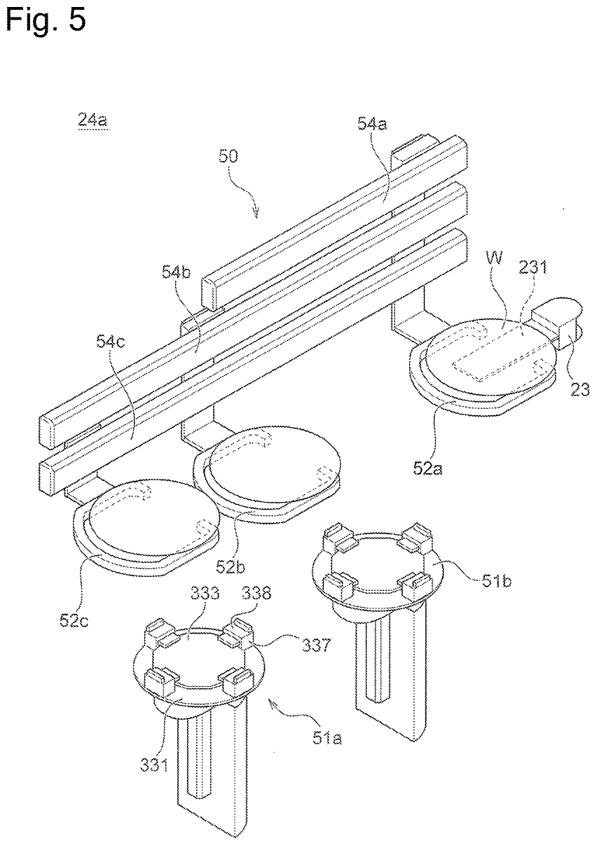

The second transfer unit 24b has a configuration similar to the first transfer unit 24a; therefore, the following describes the first transfer unit 24a. FIG. 5 is a perspective view illustrating the first transfer unit 24a.

As illustrated in FIG. 5, the first transfer unit 24a includes a first pusher 51a, a second pusher 51b, and an exchanger 50. The first pusher 51a is located at the first substrate transfer position TP1 corresponding to the first polishing device 21a and moves up and down. The second pusher 51b is located at the second substrate transfer position TP2 corresponding to the second polishing device 21b and moves up and down. The exchanger 50 includes a first stage 52a, a second stage 52b, and a third stage 52c that horizontally move between the first substrate transfer position TP1 and the second substrate transfer position TP2 independently of one another.

Among these members, the first pusher 51a delivers the substrate W held to any of the first to the third stages 52a to 52c to the top ring 25a in the first polishing device 21a and also delivers the substrate W after polishing in the first polishing device 21a to any of the first to the third stages 52a to 52c. The second pusher 51b delivers the substrate W held to any of the first to the third stages 52a to 52c to the top ring 25b in the second polishing device 21b and also delivers the substrate W after polishing in the second polishing device 21b to any of the first to the third stages 52a to 52c. Thus, the first pusher 51a and the second pusher 51b function as a delivery mechanism that delivers the substrate W between the exchanger 50 and the respective top rings. The second pusher 51b has a structure similar to the first pusher 51a; therefore, the following describes only the first pusher 51a.

The first pusher 51a includes a guide stage 331 to hold the top ring 25a on the first polishing device 21a and a push stage 333 to hold the substrate W. Four top ring guides 337 are installed to an outermost periphery of the guide stage 331. An upper stepped portion 338 on the top ring guide 337 is an accessing portion with a lower surface of a guide ring of the top ring (surrounding the outer periphery of the substrate W, not illustrated). The upper stepped portion 338 is provided with a taper (preferably from around 25° to 35°) to introduce the top ring. During unloading of the substrate, the top ring guides 337 directly receive an edge of the substrate.

The guide stage 331 is movable in the up-down direction. The push stage 333 is located on the upper side of the guide stage 331. On the center of the push stage 333, an electric actuator that moves up and down the push stage 333 with respect to the guide stage 331 is disposed. The push stage 333 moves up and down by the electric actuator to load the substrate W to the top ring. in this embodiment, the push stage 333 driven by the electric actuator can position the push stage 333 at a desired height position. Thus, when the push stage 333 receives the substrate W, the push stage 333 can be stood by immediately below the substrate W as a preliminary operation, thereby ensuring shortening a period required for the receiving operation.

As illustrated in FIG. 5, the exchanger 50 includes the first stage 52a, the second stage 52b, and the third stage 52c located in multiple stages up and down. In the example illustrated in the drawing, the first stage 52a is located in the lower stage, the second stage 52b is located in the medium stage, and the third stage 52c is located in the upper stage. While the first stage 52a, the second stage 52b, and the third stage 52c move on an identical axis line passing through the first substrate transfer position TP1 and the second substrate transfer position TP2 in plan view, the installation heights are different and therefore the first stage 52a, the second stage 52b, and the third stage 52c are freely movable without interference with one another.

As illustrated in FIG. 5, the first stage 52a is provided with a first stage driving mechanism 54a that linearly moves the first stage 52a in a uniaxial direction. The second stage 52b is provided with a second stage driving mechanism 54b that linearly moves the second stage 52b in the uniaxial direction. The third stage 52c is provided with a third stage driving mechanism 54c that linearly moves the third stage 52c in the uniaxial direction. As the first to the third stage driving mechanisms 54a to 54c, for example, electric actuators or motor-driving mechanisms using ball screws are used. The first to the third stages 52a to 52c receive powers from the respective different first to the third stage driving mechanisms 54a to 54c to be movable in different directions at respective different timings.

The second stage 52b and the third stage 52c have configurations similar to the first stage 52a; therefore, the following describes the first stage 52a.

As illustrated in FIG. 5, the first stage 52a has a “U” shape in plan view where one side (rear-right side in FIG. 5) in a linear movement direction by the first stage driving mechanism 54a is open. Therefore, with the first stage 52a located at the first substrate transfer position TP1, the first pusher 51a is movable up and down so as to pass through the inside of the U-shaped first stage 52a. Even when the first pusher 51a passes through the inside of the first stage 52a, the first stage 52a is movable to the other side (the front-left side in FIG. 5) in the linear movement direction.

Although the illustration is omitted, the first stage 52a includes four pins protruding upward. Therefore, the substrate placed on the first stage 52a is supported on the first stage 52a with an outer peripheral edge of the substrate is guided by the four pins to be positioned. These pins are made of resin such as polypropylene (PP), polychlorotrifluoroethylene (PCTFE), and polyether ether ketone (PEEK).

<Cleaning Unit>

As illustrated in FIG. 1, the cleaning unit 13 is a region to clean the substrate after polishing and includes a first cleaning unit 30a. Cleaning units having similar configurations may be located in two stages, up and down, in the cleaning unit 13. Locating the two cleaning units having the similar configurations allows improving a throughput of the cleaning process.

As illustrated in FIG. 1, the first cleaning unit 30a includes a plurality of (four in the example illustrated in the drawing) cleaning modules 311a, 312a, 313a, and 314a, a substrate station 33a, a preliminary cleaning module 39a, and a first cleaning unit transfer mechanism 32a that transfers the substrate W between the respective cleaning modules 311a to 314a and 39a and the substrate station 33a. The plurality of cleaning modules 311a to 314a and 39a and the substrate station 33a are located in series along a longitudinal direction of the substrate processing apparatus 10. In an upper portion of the respective cleaning modules 311a to 314a and 39a, a filter fan unit (not illustrated) including a clean air filter is disposed. This filter fan unit always blows out clean air from which particles have been removed downward. The inside of the first cleaning unit 30a is always maintained at a pressure higher than the polishing unit 12 to prevent the particles from the polishing unit 12 from flowing in.

The transfer robot 23 in the polishing unit 12 can access the substrate station 33a. Accordingly, the substrate W polished by the polishing unit 12 is transferred to the substrate station 33a with the transfer robot 23. The first cleaning unit transfer mechanism 32a can access the substrate station 33a.

As illustrated in FIG. 1, the four cleaning modules 311a to 314a (hereinafter referred to as first to fourth cleaning modules in some cases) are located in series in this order from the substrate station 33a. The cleaning modules 311a to 314a each includes a cleaning machine (not illustrated).

As the cleaning machines in the first cleaning module 311a and the second cleaning module 312a, for example, roll-type cleaning machines that rotate roll-shaped sponges located up and down and press the sponges against a front surface and a back surface of the substrate to clean the front surface and the back surface of the substrate are usable. As the cleaning machine in the third cleaning module 313a, for example, a pencil-type cleaning machine that presses a hemispherical sponge against the substrate while rotating the sponge to clean the substrate is usable. As the cleaning machine in the fourth cleaning module 314a, for example, a pencil-type cleaning machine that can clean the back surface of the substrate with rinse and presses a hemispherical sponge against the front surface of the substrate while rotating the sponge to clean the front surface is usable. This cleaning machine in the fourth cleaning module 314a includes a stage to rotate a chucked substrate at high-speed and has a function to dry the substrate after cleaning through the high-speed rotation of the substrate (spin dry function). In addition to the above-described roll-type cleaning machine and pencil-type cleaning machine, a megasonic cleaning machine that applies ultrasonic waves to cleaning fluid to clean the substrate may be additionally provided as the cleaning machine in each of the cleaning modules 311a to 314a. The preliminary cleaning module 39a can include any cleaning machine including the above-described cleaning machines. In one embodiment, the preliminary cleaning module 39a can be configured as a buff processing device (for example, a device described in FIG. 1 of Japanese Unexamined Patent Application Publication No. 2016-43471) that relatively moves a substrate W and a buff pad while the substrate W is brought in contact with the buff pad and slurry is interposed between the substrate W and the buff pad to polish and/or scrub the surface of the substrate W. The first cleaning unit transfer mechanism 32a can access the respective cleaning modules 311a to 314a and 39a.

The above-described substrate processing apparatus uses a substrate transfer system to move the substrate to the various units and performs various processes such as polishing and cleaning the substrate. In the above-described embodiment, the transfer robot 111, the polishing unit transfer mechanism 22, the transfer unit 14, the transfer robot 23, the first cleaning unit transfer mechanism 32a, the substrate station 33a, the first transfer unit 24a, the second transfer unit 24b, and the like constitute the substrate transfer system. For the substrate transfer system to accurately transfer the substrate, a teaching work teaching an operation of the substrate transfer system is necessary. For example, stop positions of the robot arm holding the substrate and the movable stage are taught. Conventionally, a person performs such teaching work while visually checking the stop positions of the robot arm holding the substrate and the movable stage, and this has required a lot of time to perform the teaching work at the start-up and during the maintenance. Moreover, a problem arises that accuracy of the work varies depending on experience and a skill of a worker who performs the teaching work.

This application discloses a teaching apparatus and a teaching method for the substrate transfer system. As one example, the following describes a teaching apparatus 400 for the substrate transfer system of the above-described substrate processing apparatus 10. The teaching apparatus 400 that includes a camera 410 according to one embodiment uses a teaching substrate TW and a controller 402. In short, the teaching apparatus 400 calculates a relative position between the substrate transfer device and a substrate receiving device appropriate for delivery of the teaching substrate TW based on an image of the camera 410 mounted to the teaching substrate TW and determines operations by the substrate transfer device and the substrate receiving device based on the calculated position.

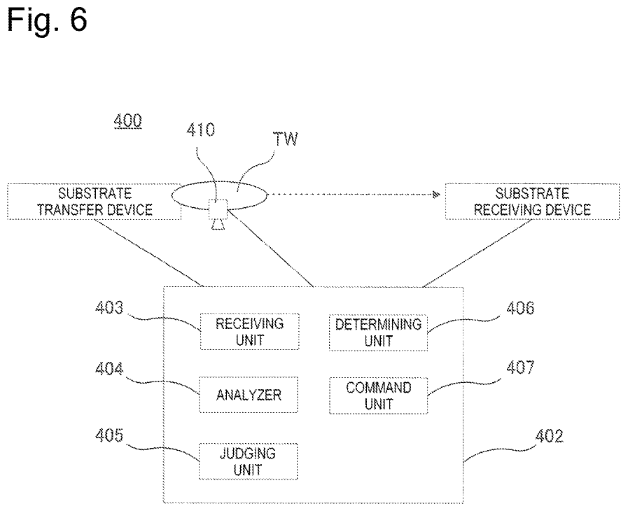

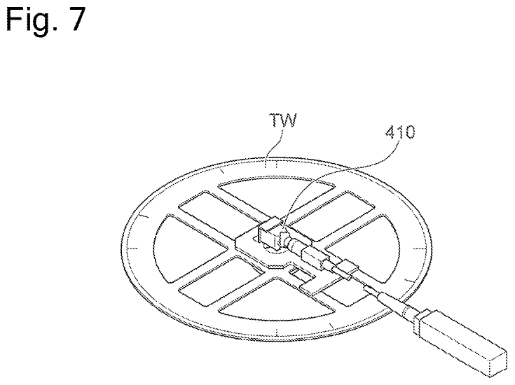

FIG. 6 is a drawing schematically illustrating a configuration of the teaching apparatus 400 according to the one embodiment. As illustrated in the drawing, the teaching apparatus 400 uses the teaching substrate TW. FIG. 7 is a perspective view illustrating the teaching substrate TW according to the one embodiment. The teaching substrate TW can be designed as one having dimensions similar to those of the substrate W, the process target of the substrate processing apparatus 10. For example, in a case where the substrate processing apparatus 10 processes the circular substrate W, the teaching substrate TW can be designed as a circular substrate having a radius identical to a radius of the substrate W processed by the substrate processing apparatus 10. The teaching substrate TW includes the camera 410. The camera 410 can be, for example, a CCD camera and a CMOS camera. The camera 410 is located at the center of the teaching substrate TW. The camera 410 is oriented in a direction perpendicular to the teaching substrate TW, thus ensuring photographing an image in the direction perpendicular to the teaching substrate TW. As illustrated in FIG. 6, the substrate transfer device transfers the teaching substrate TW to the substrate receiving device. These substrate transfer device and substrate receiving device are, for example, the transfer robot 111, the polishing unit transfer mechanism 22, the transfer unit 14, the transfer robot 23, the first cleaning unit transfer mechanism 32a, the substrate station 33a, the first transfer unit 24a, and the second transfer unit 24b constituting the substrate transfer system of the substrate processing apparatus 10. Whether to serve as the substrate transfer device or the substrate receiving device depends on a relative role when the teaching substrate TW is transferred or the substrate W is transferred. For example, when the transfer robot 23 receives the teaching substrate TW from the transfer unit 14 in the substrate processing apparatus 10, the transfer unit 14 serves as the substrate transfer device and the transfer robot 23 serves as the substrate receiving device. When the transfer robot 23 transfers the teaching substrate TW to the first transfer unit 24a, the transfer robot 23 serves as the substrate transfer device and the first transfer unit 24a serves as the substrate receiving device.

As illustrated in FIG. 6, the controller 402 includes a receiving unit 403, an analyzer 404, a judging unit 405, a determining unit 406, and a command unit 407. The receiving unit 403 receives the image photographed by the camera 410. The camera 410 and the controller 402 may be communicatively coupled with wire or may be communicatively coupled wirelessly. Although details will be described later, the analyzer 404 analyzes the image received by the receiving unit 403 and calculates a relative positional relationship between the substrate transfer device and the substrate receiving device. The command unit 407 issues an operation command to the substrate transfer device and/or the substrate receiving device based on the relative positional relationship calculated by the analyzer 404. The controller 402 can be configured of a general computer including a memory, a processor, an input/output device, and a similar device. In one embodiment, the controller 402 may be configured as software for teaching mounted in hardware identical to the control unit 15 in the substrate processing apparatus 10. In one embodiment, the controller 402 may be configured of, for example, a computer separated from the control unit 15 that can communicate with the control unit 15 in the substrate processing apparatus 10.

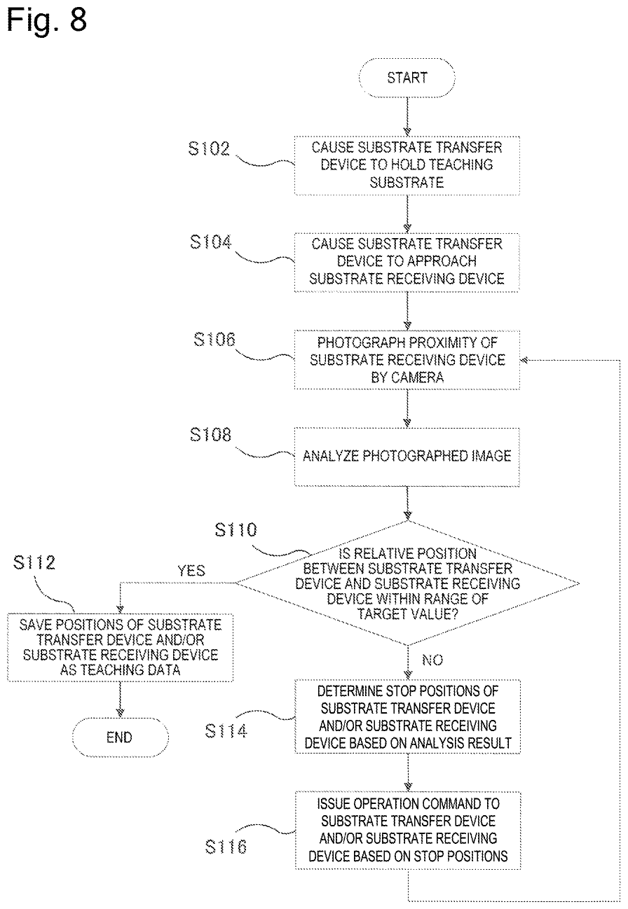

The following describes the teaching method for the substrate transfer system using the above-described teaching apparatus 400. FIG. 8 is a flowchart depicting the teaching method for the substrate transfer system according to one embodiment. As one example, the following describes a case where the operation of transferring the substrate W from the first stage 52a to the first pusher 51a in the exchanger 50 is taught in the substrate processing apparatus 10. In this case, the first stage 52a in the exchanger 50 serves as the substrate transfer device and the first pusher 51a serves as the substrate receiving device. First, the substrate transfer device is caused to hold the teaching substrate TW to which the camera 410 is mounted (S102). At this time, the camera 410 is oriented so as to ensure photographing the substrate receiving device and the substrate transfer device is caused to hold the teaching substrate TW. In one embodiment, the teaching substrate TW may be located in the front loading unit 113 and the teaching substrate TW may be automatically transferred to the first stage 52a using the transfer system of the substrate processing apparatus 10. At this time, the teaching substrate TW may be transferred to the first stage 52a by control identical to the usual operation that the substrate processing apparatus 10 transfers s the substrate W as the process target. Alternatively, the teaching substrate TW may be manually located on the first stage 52a.

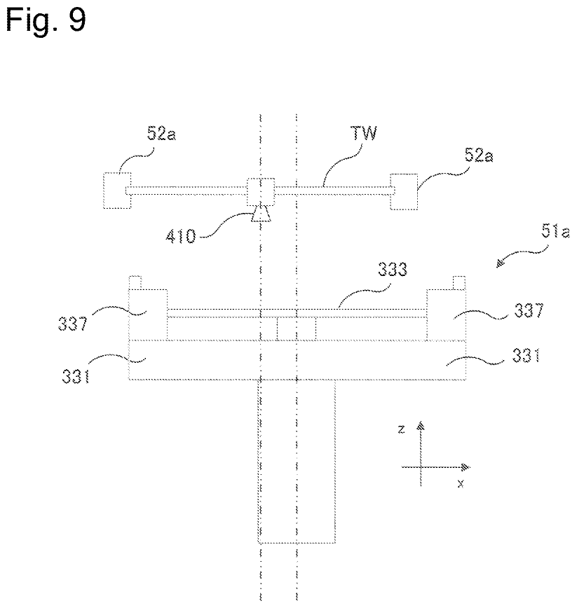

Next, the substrate transfer device holding the teaching substrate TW is caused to approach the substrate receiving device (S104). At this time, the substrate transfer device may be moved, the substrate receiving device may be moved, or both may be moved. The operation of approaching the substrate transfer device holding the teaching substrate TW to the substrate receiving device can be performed by control identical to the usual operation when the substrate processing apparatus 10 transfers the substrate W as the process target. In the example of the first stage 52a in the exchanger 50 serving as the substrate transfer device and the first pusher 51a serving as the substrate receiving device, the first stage 52a is moved just above the first pusher 51a. FIG. 9 is a side view schematically illustrating a state where the first stage 52a in the exchanger 50 moves near just above the first pusher 51a.

Next, the proximity of the substrate receiving device is photographed by the camera 410 mounted to the teaching substrate TW (S106). The photographed image is transmitted to the receiving unit 403 in the controller 402. Note that when the substrate receiving device is photographed by the camera 410, the substrate transfer device holding the teaching substrate WT is stopped. A distance between the substrate transfer device and the substrate receiving device during photographing is set in a range of a distance in which the camera 410 can photograph a mark 450 described later on the substrate receiving device.

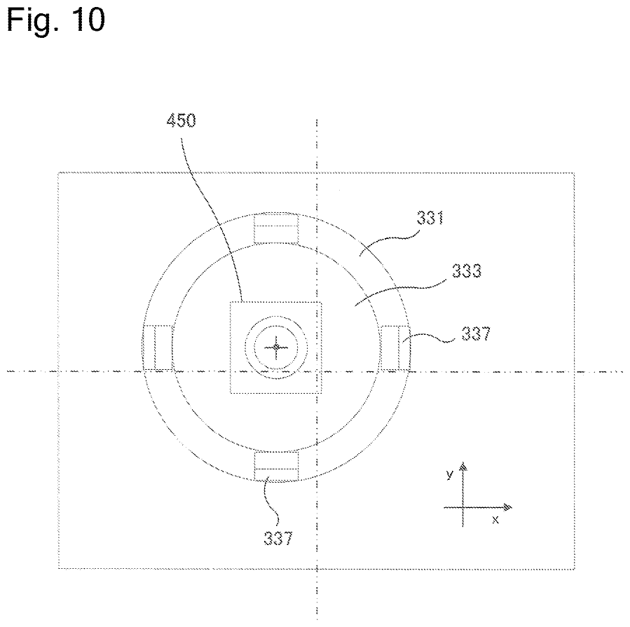

Next, the analyzer 404 in the controller 402 analyzes the received image (S108). More specifically, the relative positional relationship between the substrate transfer device and the substrate receiving device is calculated from the photographed image. In one embodiment, the substrate receiving device includes the mark 450 (see FIG. 10). Therefore, the photographed image includes the mark 450 on the substrate receiving device. As one example, the push stage 333 on the first pusher 51a includes the mark 450. FIG. 10 is a drawing schematically illustrating an image photographed when the first stage 52a and the first pusher 51a in the exchanger 50 are in the state illustrated in FIG. 9. As illustrated in FIG. 10, the photographed image includes the mark 450 on the push stage 333. In the example illustrated in FIG. 10, the mark 450 is formed of double circles and a square boxing the double circles. The centers of the circles and the center of the square of the mark 450 are positioned at the center of the circular push stage 333 corresponding to the center of the received substrate W. As described above, the camera 410 is located at the center of the teaching substrate TW. Therefore, a comparison between the center position of the photographed image and the center position of the mark 450 in the image allows calculating a relative position between the substrate transfer device and the substrate receiving device in a planar direction (x-y-direction in FIG. 10) of the teaching substrate TW. Additionally, the relative position between the substrate transfer device and the substrate receiving device in a direction (z-direction in FIG. 9) perpendicular to a plane of the teaching substrate TW can be calculated from a size of the mark 450 in the image, for example, radii of the circles and a length of a side of the square. While the mark 450 is formed of the double circles and the square boxing the double circles in the embodiment illustrated in FIG. 10, as long as the image is recognizable, the mark 450 has any shape and size. Examples of the shape of the mark 450 can include shapes symmetric in the x-y-direction, such as a square, a rectangle, and a parallelogram. As one embodiment, the mark 450 needs not to be a component newly added for teaching according to this disclosure but, for example, a component of the substrate receiving device may be used as the mark 450. For example, since the four top ring guides 337 are located on the first pusher 51a, these top ring guides 337 may serve as the marks 450. In this case, for example, connecting the centers of the four top ring guides 337 can form a quadrilateral; therefore, the relative position between the substrate transfer device and the substrate receiving device can be calculated from the size of this quadrilateral and the center position of the quadrilateral. At this time, as long as having a symmetrical shape in the x-y-direction, such as a square, a rectangle, and a parallelogram, this quadrilateral is usable as the mark 450. As one embodiment, the teaching apparatus 400 can use a target substrate including a mark. The target substrate can be designed as one having dimensions similar to those of the substrate W processed by the substrate processing apparatus. The target substrate can include the mark similar to the above-described mark 450 on the push stage 333. In this case, photographing by the camera 410 while the substrate receiving device holds the target substrate allows calculating the relative position between the substrate transfer device and the substrate receiving device through the analysis similar to the above-described analysis. The use of the target substrate allows performing the teaching even when the mark 450 cannot be given to the substrate receiving device and the substrate receiving device does not have a component usable as a mark.

Next, the judging unit 405 in the controller 402 compares the relative position between the substrate transfer device and the substrate receiving device with a target position and judges whether a deviation from the target position is within a predetermined range (S110). The target position is a relative position between the substrate transfer device and the substrate receiving device when delivery of the substrate starts between the substrate transfer device and the substrate receiving device. Alternatively, the target position can also be referred to as an ideal relative position on design when the delivery of the substrate starts between the substrate transfer device and the substrate receiving device. An allowable range of the deviation can be set to, for example, ±0.5 mm from the target position. The allowable range of deviation may differ between the x-y-direction and the z-direction.

In a case of the relative position between the substrate transfer device and the substrate receiving device within the range of the target, the positions of the substrate transfer device and/or the substrate receiving device are stored as teaching data (S112). The storage destination may be a storage medium provided with the control unit 15 or can be a storage medium accessible by the control unit 15. As one embodiment, when the substrate transfer device and/or the substrate receiving device is driven by a pulse motor, the number of pulses given to move the substrate transfer device and/or the substrate receiving device at Step S104 can be stored as the teaching data.

In a case of the relative position between the substrate transfer device and the substrate receiving device outside the range of the target, the determining unit 406 determines moving amounts of the substrate transfer device and/or the substrate receiving device, that is, new stop positions, based on the deviation amount (S114).

Next, the command unit 407 issues the operation command to the substrate transfer device and/or the substrate receiving device based on the determined moving amount to move the substrate transfer device and/or the substrate receiving device (S116). After that, by newly repeating the step of photographing the substrate receiving device by the camera 410 and the subsequent steps, the relative position between the substrate transfer device and the substrate receiving device is set to be within the range of the target, thus ensuring obtaining the teaching data.

After the teaching data is stored, the teaching substrate TW is delivered from the substrate transfer device to the substrate receiving device, the substrate receiving device that has received the substrate is defined as a new substrate transfer device, and a destination to which the substrate is transferred next is defined as a new substrate receiving device, and thus the above-described teaching may be sequentially repeated. Doing so allows performing the teaching at a plurality of, preferably all, sites in the substrate transfer system of the substrate processing apparatus 10.

In one embodiment, when the relative position between the substrate transfer device and the substrate receiving device is outside the range of the target after the photographed image is analyzed (S108), the stop positions of the substrate transfer device and/or the substrate receiving device may be determined based on the deviation amount and the stop positions may be stored as the teaching data. When the moving amount to correct the deviation is found, the moving amount for movement to the target position can also be found. Therefore, it is not always necessary to move the substrate transfer device and/or the substrate receiving device again, actually move the substrate transfer device and/or the substrate receiving device until the substrate transfer device and/or the substrate receiving device reach the target positions, and photograph, analyze, and confirm the image again.

In one embodiment, the substrate processing apparatus 10 records the stop positions of the driving mechanisms such as the transfer robot and the movable stage in the transfer system during the transfer of the substrate to perform a process on the substrate. In one embodiment, not only the stop position of the driving mechanism, but also data such as positions of the driving mechanism for several seconds before reaching the stop position may be stored. Storing the data such as the positions of the driving mechanism for several seconds before reaching the stop position can confirm a behavior of the driving mechanism during braking. The data such as the stop position of the driving mechanism can be recorded in, for example, the storage medium in the control unit 15 or the storage medium accessible by the control unit 15. As described above, since the substrate processing apparatus 10 stores the stop position of the driving mechanism in the transfer system as the teaching data, a comparison between the data such as the stop position of the driving mechanism in the substrate process with the teaching data as the optimal position allows sensing a failure in the transfer system. In one embodiment, not only the stop position of the driving mechanism, but also the data such as the positions of the driving mechanism for several seconds before reaching the stop position may be obtained as the teaching data when the stop position is obtained as the teaching data. In one embodiment, the substrate transfer system is determined as having an error when a difference between the teaching data of the stop position and the actual stop position of the driving mechanism in the substrate process exceeds a predetermined value. Further, analyzing the recorded actual stop position of the driving mechanism in the substrate process allows predicting a fault of the driving mechanism. For example, whether the deviation amount between the stop position of the driving mechanism and the taught stop position gradually increases in one direction in association with the increase in the number of usages or whether the stop position is displaced suddenly or randomly can be found. In the case where the deviation amount increases in one direction in association with the increase in the number of usages, assuming that the relative position between the substrate transfer device and the substrate receiving device is within the range of the target value in the above-described Step S110, when the deviation amount is increasing in the usage history, a new stop position may be determined when the teaching work is performed during maintenance and the like.

According to the above-described embodiments, the teaching can be accurately performed irrespective of a skill of a worker who performs the teaching work.

At least the following technical ideas are grasped from the above-described embodiments.

[Configuration 1]

According to Configuration 1, there is provided a teaching apparatus for a substrate transfer system including a substrate transfer device and a substrate receiving device. The substrate transfer device is configured to hold a substrate. The substrate receiving device is configured to receive the substrate from the substrate transfer device. The teaching apparatus includes a teaching substrate configured to be held to the substrate transfer device, a camera mountable to the teaching substrate, and a controller for controlling an operation of the substrate transfer device holding the teaching substrate and/or the substrate receiving device. The controller includes a receiving unit that receives an image photographed by the camera, an analyzer that calculates a relative positional relationship between the substrate transfer device and the substrate receiving device from the received image, and a determining unit that determines a stop position of the substrate transfer device and/or the substrate receiving device based on the relative positional relationship between the substrate transfer device and the substrate receiving device calculated by the analyzer.

[Configuration 2]

According to Configuration 2, in the teaching apparatus of Configuration 1, the analyzer calculates the relative positional relationship between the substrate transfer device and the substrate receiving device based on a mark in the image photographed by the camera.

[Configuration 3]

According to Configuration 3, in the teaching apparatus of Configuration 2, the substrate receiving device includes the mark.

[Configuration 4]

According to Configuration 4, in the teaching apparatus of Configuration 2, the substrate receiving device is configured to receive a target substrate including the mark.

[Configuration 5]

According to Configuration 5, in the teaching apparatus of any one of configurations of Configuration 2 to Configuration 4, the analyzer calculates the relative positional relationship between the substrate transfer device and the substrate receiving device based on a position of the mark in the image.

[Configuration 6]

According to Configuration 6, in the teaching apparatus of any one of configurations of Configuration 2 to Configuration 5, the analyzer calculates the relative positional relationship between the substrate transfer device and the substrate receiving device based on a size of the mark in the image.

[Configuration 7]

According to configuration 7, in the teaching apparatus of any one of configurations of Configuration 1 to Configuration 6, the controller includes a command unit that issues an operation command to the substrate transfer device and/or the substrate receiving device based on the stop position determined by the determining unit.

[Configuration 8]

According to Configuration 8, a teaching method for a substrate transfer system including a substrate transfer device and a substrate receiving device is provided. The substrate transfer device is configured to hold a substrate. The substrate receiving device is configured to receive the substrate from the substrate transfer device. The teaching method includes: causing the substrate transfer device to hold a teaching substrate to which a camera is mounted; causing the substrate transfer device and/or the substrate receiving device to move such that the substrate transfer device relatively approaches the substrate receiving device; photographing a proximity of the substrate receiving device by the camera; calculating a relative positional relationship between the substrate transfer device and the substrate receiving device from an image photographed by the camera; and determining a stop position of the substrate transfer device and/or the substrate receiving device based on the calculated relative positional relationship between the substrate transfer device and the substrate receiving device.

[Configuration 9]

According to Configuration 9, in the teaching method of Configuration 8, the calculating calculates the relative positional relationship between the substrate transfer device and the substrate receiving device based on a mark in the image photographed by the camera.

[Configuration 10]

According to Configuration 10, in the teaching method of Configuration 9, the teaching method includes photographing the mark included in the substrate receiving device by the camera.

[Configuration 11]

According to Configuration 11, in the teaching method of Configuration 9, the teaching method includes holding a target substrate including the mark by the substrate receiving device and photographing the target substrate held to the substrate receiving device by the camera.

[Configuration 12]

According to Configuration 12, in the teaching method of any one of configurations of Configuration 9 to Configuration 11, the calculating calculates the relative positional relationship between the substrate transfer device and the substrate receiving device based on a position of the mark in the image.

[Configuration 13]

According to Configuration 13, in the teaching method of any one of configurations of Configuration 9 to Configuration 11, the calculating calculates the relative positional relationship between the substrate transfer device and the substrate receiving device based on a size of the mark in the image.

[Configuration 14]

According to Configuration 14, in the teaching method of any one of configurations of Configuration 9 to Configuration 12, the teaching method includes issuing an operation command to the substrate transfer device and/or the substrate receiving device based on the determined stop position.

[Configuration 15]

According to Configuration 15, there is provided a method for predicting a fault for a substrate transfer system including a substrate transfer device and a substrate receiving device. The substrate transfer device is configured to hold a substrate. The substrate receiving device is configured to receive the substrate from the substrate transfer device. The method includes recording a stop position of the substrate transfer device and/or the substrate receiving device while the substrate transfer system is in operation, and analyzing the recorded stop position.

[Configuration 16]

According to Configuration 16, in the method of Configuration 15, the analyzing includes comparing the stop position of the substrate transfer device and/or the substrate receiving device while the substrate transfer system is in operation with teaching data indicative of an optimal stop position of the substrate transfer device and/or the substrate receiving device. Note that the teaching data may be obtained by any method, and, for example, may be obtained by the teaching apparatuses and the teaching methods disclosed in this specification.

### REFERENCE SIGNS LIST

10 . . . substrate processing apparatus

11 . . . loading/unloading unit

12 . . . polishing unit

13 . . . cleaning unit

14 . . . transfer unit

15 . . . control unit

22 . . . polishing unit transfer mechanism

23 . . . transfer robot

24a . . . first transfer unit

24b . . . second transfer unit

32a . . . first cleaning unit transfer mechanism

50 . . . exchanger

51a . . . first pusher

54a . . . first stage driving mechanism

111 . . . transfer robot

33a . . . substrate station

400 . . . teaching apparatus

402 . . . controller

403 . . . receiving unit

404 . . . analyzer

405 . . . judging unit

406 . . . determining unit

407 . . . command unit

410 . . . camera

450 . . . mark

W . . . substrate

TW . . . teaching substrate

What is claimed is:

1. A teaching apparatus for a substrate transfer system, wherein
the substrate transfer system includes a substrate transfer device and a substrate receiving device, the substrate transfer device is configured to hold a substrate, and the substrate receiving device is configured to receive the substrate from the substrate transfer device,
the teaching apparatus comprises:
a teaching substrate configured to be held to the substrate transfer device;
a camera mountable to the teaching substrate; and
a controller for controlling an operation of the substrate transfer device holding the teaching substrate and/or the substrate receiving device, and
the controller includes:
a receiving unit that receives an image photographed by the camera;
an analyzer that calculates a relative positional relationship between the substrate transfer device and the substrate receiving device from the received image; and
a determining unit that determines a stop position of the substrate transfer device and/or the substrate receiving device based on the relative positional relationship between the substrate transfer device and the substrate receiving device calculated by the analyzer.

2. The teaching apparatus according to claim 1, wherein
the analyzer calculates the relative positional relationship between the substrate transfer device and the substrate receiving device based on a mark in the image photographed by the camera.

3. The teaching apparatus according to claim 2, wherein
the substrate receiving device includes the mark.

4. The teaching apparatus according to claim 2, wherein
the substrate receiving device is configured to receive a target substrate including the mark.

5. The teaching apparatus according to claim 2, wherein
the analyzer calculates the relative positional relationship between the substrate transfer device and the substrate receiving device based on a position of the mark in the image.

6. The teaching apparatus according to claim 2, wherein
the analyzer calculates the relative positional relationship between the substrate transfer device and the substrate receiving device based on a size of the mark in the image.

7. The teaching apparatus according to claim 1, wherein
the controller includes a command unit that issues an operation command to the substrate transfer device and/or the substrate receiving device based on the stop position determined by the determining unit.

8. A teaching method for a substrate transfer system including a substrate transfer device and a substrate receiving device, the substrate transfer device being configured to hold a substrate, the substrate receiving device being configured to receive the substrate from the substrate transfer device, the teaching method comprising:
causing the substrate transfer device to hold a teaching substrate to which a camera is mounted;
causing the substrate transfer device and/or the substrate receiving device to move such that the substrate transfer device relatively approaches the substrate receiving device;
photographing a proximity of the substrate receiving device by the camera;
calculating a relative positional relationship between the substrate transfer device and the substrate receiving device from an image photographed by the camera; and
determining a stop position of the substrate transfer device and/or the substrate receiving device based on the calculated relative positional relationship between the substrate transfer device and the substrate receiving device.

9. The teaching method according to claim 8, wherein
the calculating calculates the relative positional relationship between the substrate transfer device and the substrate receiving device based on a mark in the image photographed by the camera.

10. The teaching method according to claim 9, comprising
photographing the mark included in the substrate receiving device by the camera.

11. The teaching method according to claim 9, comprising:
holding a target substrate including the mark by the substrate receiving device; and
photographing the target substrate held to the substrate receiving device by the camera.

12. The teaching method according to claim 9, wherein
the calculating calculates the relative positional relationship between the substrate transfer device and the substrate receiving device based on a position of the mark in the image.

13. The teaching method according to claim 9, wherein
the calculating calculates the relative positional relationship between the substrate transfer device and the substrate receiving device based on a size of the mark in the image.

14. The teaching method according to claim 9, comprising
issuing an operation command to the substrate transfer device and/or the substrate receiving device based on the determined stop position.

15. A method for predicting a fault for a substrate transfer system including a substrate transfer device and a substrate receiving device, the substrate transfer device being configured to hold a substrate, the substrate receiving device being configured to receive the substrate from the substrate transfer device, the method comprising:
recording a stop position of the substrate transfer device and/or the substrate receiving device while the substrate transfer system is in operation; and
analyzing the recorded stop position.

16. The method according to claim 15, wherein
the analyzing includes comparing the stop position of the substrate transfer device and/or the substrate receiving device while the substrate transfer system is in operation with teaching data indicative of an optimal stop position of the substrate transfer device and/or the substrate receiving device.
